(19) United States
(12) Patent Application Publication
(10) Pub. No.: US 2025/0125231 A1
(43) Pub. Date: Apr. 17, 2025

(54) Direct Bonded Semiconductor Die Package

(71) Applicant: Wolfspeed, Inc., Durham, NC (US)

(72) Inventors: Devarajan Balaraman, Apex, NC (US); Afshin Dadvand, Durham, NC (US); Daniel Ginn Richter, Raleigh, NC (US)

(21) Appl. No.: 18/488,284

(22) Filed: Oct. 17, 2023

(51) Int. Cl. H01L 23/495; H01L 23/00; H01L 25/065

(52) U.S. Cl. CPC H01L 23/49575; H01L 23/4952; H01L 23/49582; H01L 24/40; H01L 24/48; H01L 25/0657; H01L 2224/40165; H01L 2224/48091; H01L 2224/73221; H01L 2225/0651; H01L 2924/01013; H01L 2924/13064; H01L 2924/1711

(57) ABSTRACT

Semiconductor device packages are provided. In one example, the semiconductor device package includes a semiconductor die. The semiconductor die includes a wide bandgap semiconductor material. The semiconductor die includes a metallization layer on a surface of the semiconductor die. The semiconductor device package includes a submount. The metallization of the semiconductor die is directly bonded to the submount.

### FIELD

Example aspects of the present disclosure relate generally to semiconductor devices.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide bandgap semiconductor die, may need to be attached to a conductive lead frame for use in a discrete power semiconductor device package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or can be learned from the description, or can be learned through practice of the embodiments.

One example aspect of the present disclosure is directed to a semiconductor device package. The semiconductor device package includes a semiconductor die. The semiconductor die includes a wide bandgap semiconductor material. The semiconductor die includes a metallization layer on a surface of the semiconductor die. The semiconductor device package includes a submount. The metallization of the semiconductor die is directly bonded to the submount.

Another example aspect of the present disclosure is directed to a semiconductor device package. The semiconductor device package includes a semiconductor die. The semiconductor die includes a wide bandgap semiconductor material. The semiconductor die includes a metallization layer on a surface of the semiconductor die. The semiconductor device package includes an aluminum lead frame.

Another example aspect of the present disclosure is directed to a method of providing a semiconductor device package. The method includes providing a metallization layer on a surface of a semiconductor die. The semiconductor die includes a wide bandgap semiconductor. The method includes directly bonding the metallization layer to a submount using a direct bonding process.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional view of a semiconductor device package as described in the present disclosure.

FIG. 2 depicts a cross-sectional view of an example semiconductor device package according to example embodiments of the present disclosure.

FIG. 3 depicts a cross-sectional view of an example semiconductor device package according to example embodiments of the present disclosure.

FIG. 4 depicts a cross-sectional view of an example semiconductor die according to example embodiments of the present disclosure.

FIG. 5 depicts a cross-sectional view of an example semiconductor device package according to example embodiments of the present disclosure.

FIG. 6 depicts a cross-sectional view of an example semiconductor device package according to example embodiments of the present disclosure.

FIG. 7 depicts a cross-sectional view of an example semiconductor device package according to example embodiments of the present disclosure.

FIG. 8 depicts an example discrete semiconductor device package according to example embodiments of the present disclosure.

FIG. 9 depicts an example power module according to example embodiments of the present disclosure.

FIG. 10 depicts an example semiconductor device package according to example embodiments of the present disclosure.

FIG. 11 depicts a flow chart diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to semiconductor device packages (e.g., discrete semiconductor device packages and power modules) for use in semiconductor applications and other electronic applications. In some embodiments, semiconductor device packages may include one or more semiconductor die having at least one semiconductor device. For instance, the semiconductor die may include, for instance, wide bandgap semiconductor devices, such as silicon carbide-based semiconductor devices (e.g., MOSFETs, Schottky diodes), Group III nitride-based semiconductor devices (e.g., high electron mobility transistor (HEMT) devices), etc. The semiconductor die may include a substrate, such as a wide bandgap substrate, such as a silicon carbide substrate. The semiconductor die may include an epitaxial layer on the substrate, such as a wide bandgap epitaxial layer, such as silicon carbide epitaxial layer and/or a Group III-nitride epitaxial layer.

In some semiconductor device packages, one or more semiconductor die may be attached to a submount (e.g., lead frame, clip structure, directed bonded copper (DBC) submount, etc.) using a die-attach material. More particularly, the die-attach material may be deposited on the submount, and the semiconductor die (or other component) may be placed on the die-attach material. The die-attach material may be subjected to bonding or a bonding process (e.g., sintering) to secure the semiconductor die (or other component) to the die-attach material.

As used herein, the term “bonding” or “bonding process” refers to causing a transition of a material from a first form to a second form. A bonding process may or may not require attaching a component to the material. Sintering, reflow, annealing, curing, exposing to light, exposing to ultraviolet light, and ultrasonic bonding are examples of bonding processes and are encompassed by the term “bonding” or “bonding process” in the disclosure and in the claims.

The various technologies that are practiced in the semiconductor industry for die-attach may present challenges and limitations. For instance, the uniformity, performance, and reliability of the die-attach material may be adversely affected during the bonding process. In addition, semiconductor device packages may experience anomalies and/or failures resulting from deformation, delamination, shifting, and/or moving (e.g., glacial moving) of the various components of the semiconductor device package die during the bonding process of the die-attach material. These anomalies and/or failures may, in turn, affect the electrical, mechanical, and thermal properties of the resulting semiconductor device package.

A variety of factors may affect whether these anomalies and/or failures arise during the semiconductor manufacturing process (e.g., during the bonding process). Such factors affecting the uniformity, performance, and reliability of the resulting semiconductor device package may include the composition of the die-attach material and the nature of the bonding process used during the semiconductor manufacturing process.

In addition, the materials used to create a die-attach material can be very costly. In some instances, precious metals such as, for example, gold, silver, or copper are used to create the die-attach material. As a result, the die-attach material may increase the cost of a semiconductor device package. Further, the inclusion of a die-attach material introduces another failure point within the semiconductor device package both during the manufacturing process and during operation.

Accordingly, example aspects of the present disclosure are directed to a semiconductor device package using a direct bonding process to attach a semiconductor die to a submount and eliminate or reduce die-attach materials. For example, the semiconductor die may be directly bonded to a submount using, for instance, an ultrasonic bonding process that binds the semiconductor die and submount together via ultrasonic vibrations without the use of a die-attach material or any intervening structure between the semiconductor die and the submount. In some embodiments, the semiconductor die may include a metallization layer made of a same material as the submount. For example, the material of the metallization layer may be a malleable metal such as aluminum, silver, or gold. In some embodiments, the submount and/or the metallization layer may have a surface roughness to facilitate bonding (e.g., ultrasonic bonding). In some examples, the surface roughness measured as arithmetic average roughness Ra may be in a range of about 0.1 μm to about 100 μm, such as about 0.5 μm to about 20 μm, such as about 0.5 μm to about 10 μm.

In some embodiments, a semiconductor die may include an aluminum metallization layer on its surface (e.g., on a substrate and/or on an epitaxial layer). The metallization layer of the semiconductor die may be directly bonded (e.g., ultrasonically bonded) to a submount such as, for example, a lead frame (e.g., aluminum lead frame), clip structure, or other submount to create at least a portion of a semiconductor device package. In some embodiments, the surface of the submount opposite the semiconductor die may be an anodized surface to assist with electrical isolation. For example, the submount may be an aluminum lead frame with a side directly bonded to a semiconductor die and the side of the lead frame opposing the directly bonded side may be anodized via oxygen exposure. The anodized surface may be an insulating layer for the submount. In some embodiments, the semiconductor device package may include an encapsulating layer (e.g., an epoxy mold compound) on one or more of the semiconductor die and the submount.

The semiconductor die may be associated with a variety of different semiconductor devices and may be directly bonded to the submount to facilitate connections to the semiconductor devices. For instance, a metallization layer on the semiconductor device may be associated with one or more contacts for semiconductor devices on the semiconductor die. For example, a MOSFET device may be on the semiconductor die and the source, gate, and drain contacts of the MOSFET device may be linked to one or more metallization layers of the semiconductor die. The metallization layer(s) may be bonded to a submount such as, for example, a lead frame creating external connections to the MOSFET device. In another embodiment, the semiconductor die may be associated with a plurality of semiconductor devices. For instance, the metallization layer of the semiconductor die may be associated with the different contacts of several MOSFETs, Schottky Diodes, or HEMTs. The semiconductor die may be directly bonded to a submount such as, for example, a lead frame via the metallization layer(s) providing external connections to the semiconductor devices. It should be appreciated that the example semiconductor devices provided herein are for example purposes only. In practice, any semiconductor device may be associated with the semiconductor die and may include a plurality of different contacts that are linked to the metallization layer(s) of the semiconductor die. For example, MOSFETs, Group III nitride-based HEMTs, silicon carbide-based Schottky diodes, or other wide bandgap semiconductor devices or transistors may be associated with the semiconductor die.

In some embodiments, the semiconductor die and/or the submount may be oriented and bonded in a variety of configurations to create a semiconductor device package. For instance, the semiconductor die may include one or more metallization layers on each of two opposing sides of the semiconductor die. For instance, the semiconductor die may include a metallization layer on a side of the semiconductor die associated with an epitaxial layer. The semiconductor die including the metallization layer on the epitaxial layer may be flipped and directly bonded to the submount. In this manner, the semiconductor die may be in a flip chip configuration and mounted to the submount. The opposing side may include a metallization layer (e.g., on the substrate of the semiconductor die). In some examples, the side of the semiconductor die facing away from the submount may be wire bonded to the submount to provide connections to one or more contacts in the metallization layer(s). For example, a semiconductor die may have a source contact and a gate contact on one side and a drain contact on an opposing parallel side. The source and gate contacts may be directly bonded to the submount (e.g., a lead frame) and the drain contact may be wire bonded to a different submount or a different portion of the same submount. In another example, the drain contact may be directly bonded to the submount (e.g., lead frame) and the source and gate contacts may be wire bonded to a different submount (e.g., lead frame) or different portion of the same submount. It should be appreciated that the configuration of contacts on the semiconductor die are for example purposes only. In practice, a plurality of different contacts may be disposed on any surface of the semiconductor die in any combination without deviating from the scope of the present disclosure.

In some embodiments, the submount may include a plurality of different layers. For instance, the submount may include one or more metal layer(s) and one or more insulating layer(s). In some embodiments, the submount may include an insulating layer between two metal layers. The metal layer(s) may be directly bonded to, for example, the semiconductor die on one side and another submount (e.g., a lead frame or clip structure), for instance, on the other side. In some embodiments, the metal layer(s) may be a malleable metal such as silver, gold, or aluminum and the insulating layer may be a ceramic. In some embodiments, the submount may be directly bonded via ultrasonic bonding to the semiconductor die and, on an opposing side, directly bonded to another submount such as, for example, a lead frame.

Aspects of the present disclosure provide a number of technical effects and benefits. For instance, aspects of the present disclosure do not require a die-attach material to electrically and/or thermally connect a semiconductor die to a submount in a semiconductor device package, reducing the failures and limitations that may be associated with die-attach materials. Additionally, use of the die-attach material may be removed or reduced from the manufacturing process, reducing or eliminating the risk of anomalies or defects caused by the manufacturing processes. For example, aspects of the present disclosure reduce, or eliminate entirely, the risk of delamination, shifting, and/or moving of the various components of a semiconductor device package during bonding processes for the die-attach material. Furthermore, reducing the die-attach materials in accordance with example aspects of the present disclosure may reduce the overall cost of a semiconductor device package. In this way, aspects of the present disclosure provide a cost-effective, controlled, and reliable semiconductor device package for use in high power and high-performance electronic applications.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

A wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

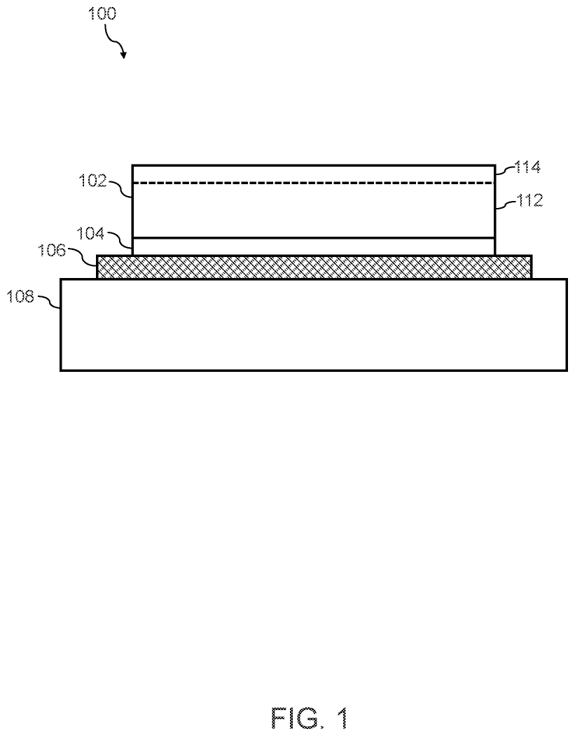

FIG. 1 depicts an example semiconductor device package 100 using a die-attach material 106 to attach a semiconductor die 102 to a submount 108. The semiconductor die 102 may include a substrate 112. The semiconductor die 102 may include an epitaxial layer on the substrate 112. The semiconductor die 102 may include a metallization layer 104, for instance, on the substrate 112. The metallization layer 104 may be in electrical and/or thermal communication with the submount 108 using the die-attach material 106. The submount 108 may be, for instance, a lead frame, a clip structure, a directed bonded copper (DBC) substrate, or other suitable structure to which a semiconductor die 102 can be mounted.

As discussed above, the uniformity, performance, and reliability of the die-attach material 106 may be adversely affected during the bonding process for the die-attach material 106 or during the manufacturing process of the semiconductor device package 100. In addition, the semiconductor device package 100 may experience anomalies and/or failures resulting from deformation, delamination, shifting, and/or moving (e.g., glacial moving) of the semiconductor die and/or other components of the semiconductor device package 100 during the bonding process of the die-attach material 106 or during the manufacturing process of the semiconductor device package 100. These anomalies and/or failures may, in turn, affect the electrical, mechanical, and thermal properties of the resulting semiconductor device package 100.

In addition, the materials used to create a die-attach material 106 can be, in some cases, very costly. In some instances, precious metals such as, for example, gold, silver, or copper are utilized to create the die-attach material 106. As a result, the die-attach material 106 may increase the cost of the semiconductor device package 100. Further, the inclusion of the die-attach material 106 may introduce another failure point within the semiconductor device package 100 both during the manufacturing process and during operation.

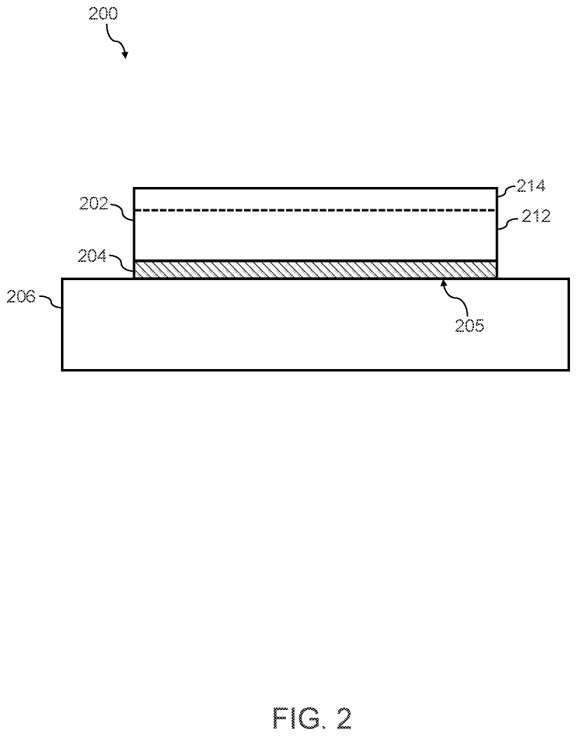

FIG. 2 depicts an example semiconductor device package 200 according to example aspects of the present disclosure. FIG. 2 is intended to represent structures for identification and description and is not intended to represent the structures to physical scale. The semiconductor device package 200 includes a semiconductor die 202 having a metallization layer 204 and a submount 206. The semiconductor die 202 may be a wide bandgap semiconductor die that includes a wide bandgap semiconductor material. For instance, the semiconductor die 202 may include a substrate 212 and an epitaxial layer 214 on the substrate 212. In some examples, the substrate 212 may be a wide bandgap semiconductor, such as silicon carbide. In some examples, the epitaxial layer 214 may be a wide bandgap semiconductor, such as silicon carbide and/or a Group III-nitride. The semiconductor die 202 may have other layers or semiconductor structures without deviating from the scope of the present disclosure. In the example of FIG. 2, the metallization layer 204 is on the substrate 212 of the semiconductor die 202.

The submount 206 may be, for instance, a lead frame. The submount 206 may be other structures to which the semiconductor die 202 is mounted in a semiconductor device package 200, such as a clip structure, DBC substrate or other submount.

The semiconductor device package 200 does not include a die-attach material. Rather, the metallization layer 204 of the semiconductor die 202 is directly bonded to the submount 206. For instance, in some examples, the metallization layer 204 of the semiconductor die 202 is directly bonded to submount 206 using an ultrasonic bonding process. There are no intervening structures between the semiconductor die 202 and the submount 206 (e.g., between the metallization layer 204 and the submount 206).

In some embodiments, the metallization layer 204 may be a malleable material, such as aluminum, silver, or gold. The submount 206 may include a malleable material (e.g., the same material as the metallization layer 204), such as aluminum, silver, or gold. In this way, the semiconductor device package 200 includes a malleable metal at an interface 205 between the metallization layer 204 and the submount 206. For instance, the metallization layer 204 and the submount 206 may each include aluminum at the interface 205 between the metallization layer 204 and the submount 206. The metallization layer 204 and the submount 206 may each include gold at the interface 205 between the metallization layer 204 and the submount 206. The metallization layer 204 and the submount 206 may each include silver at the interface 205 between the metallization layer 204 and the submount 206. There is no die-attach material or other intervening structures at the interface 205 between the semiconductor die 202 and the submount 206. The malleable metal of the metallization layer 204 and the submount 206 may be fused or bonded together during the bonding process, such as an ultrasonic bonding process.

In some instances, a surface of the submount 206 and/or the metallization layer 204 may have a surface roughness measured as arithmetic average roughness Ra in a range of about 0.1 μm to about 100 μm, such as about 0.5 μm to about 20 μm, such as about 0.5 μm to about 10 μm. The surface roughness may facilitate the direct bonding of the metallization layer 204 with the submount 206, for instance, using an ultrasonic bonding process.

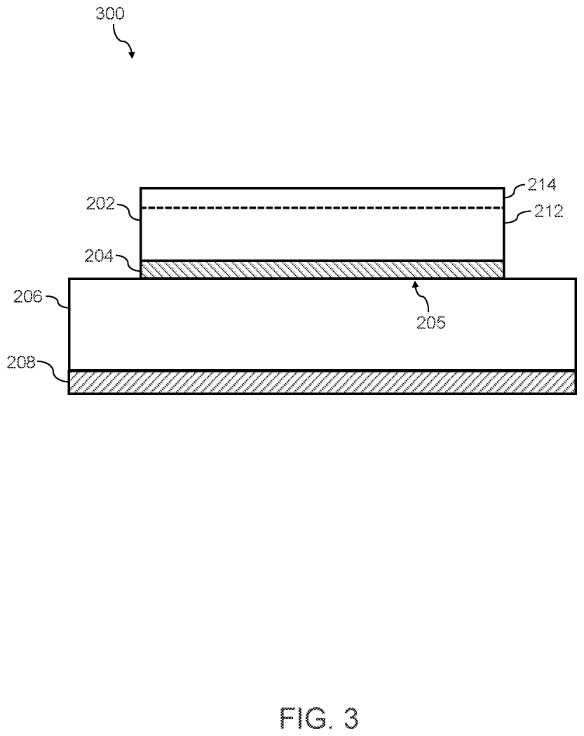

FIG. 3 depicts an example semiconductor device package 300 including an anodized surface 208 according to aspects of the present disclosure. FIG. 3 is intended to represent structures for identification and description and is not intended to represent the structures to physical scale. The semiconductor device package 300 is similar to the semiconductor device package 200 of FIG. 2. However, the semiconductor device package 300 of FIG. 3 includes an anodized surface 208. In embodiments where the submount 206 is aluminum, the anodized surface 208 may be an oxidized surface (e.g., aluminum oxide). The anodized surface 208 may provide an insulating layer for the submount 206 in the semiconductor device package 300.

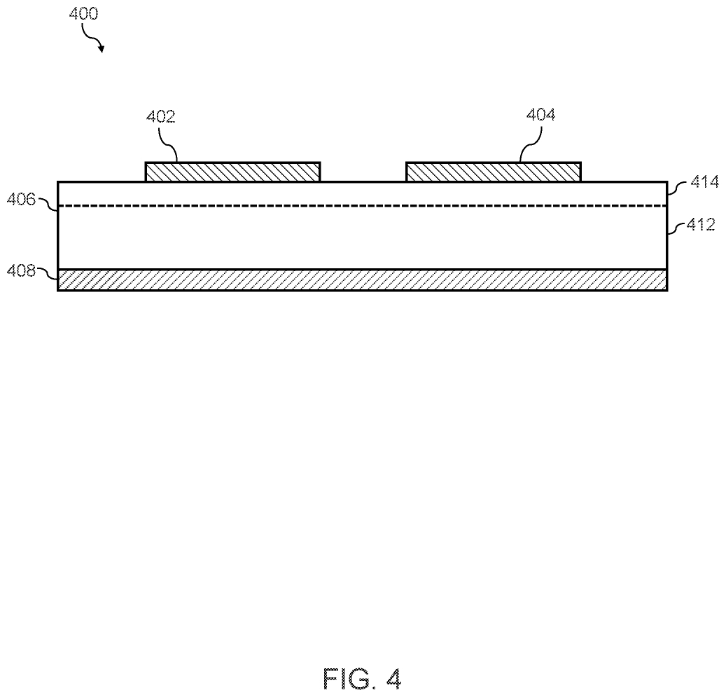

FIG. 4 depicts an example semiconductor die 400 according to aspects of the present disclosure. FIG. 4 is intended to represent structures for identification and description and is not intended to represent the structures to physical scale. The semiconductor die 400 may include a semiconductor die 406 and a first metallization layer 402 and a second metallization layer 408. For instance, the semiconductor die 402 may include a substrate 412 and an epitaxial layer 414 on the substrate 412. In some examples, the substrate 412 may be a wide bandgap semiconductor, such as silicon carbide. In some examples, the epitaxial layer 414 may be a wide bandgap semiconductor, such as silicon carbide and/or a Group III-nitride. The semiconductor die 402 may have other layers or semiconductor structures without deviating from the scope of the present disclosure. In the example of FIG. 4, the first metallization layer 404 is on the epitaxial layer 414 of the semiconductor die 402. The second metallization layer 408 is on the substrate 412 of the semiconductor die 402.

The first and second metallization layers 402, 408 may include a malleable metal such as aluminum, silver, or gold. In some embodiments, the semiconductor die 400 may include one or more contacts associated with one or more semiconductor devices, such as one or more transistor devices. For instance, the first metallization layer 402 may include a source contact and a gate contact on the epitaxial layer 414 and the second metallization layer 408 may include a drain contact on the substrate 412.

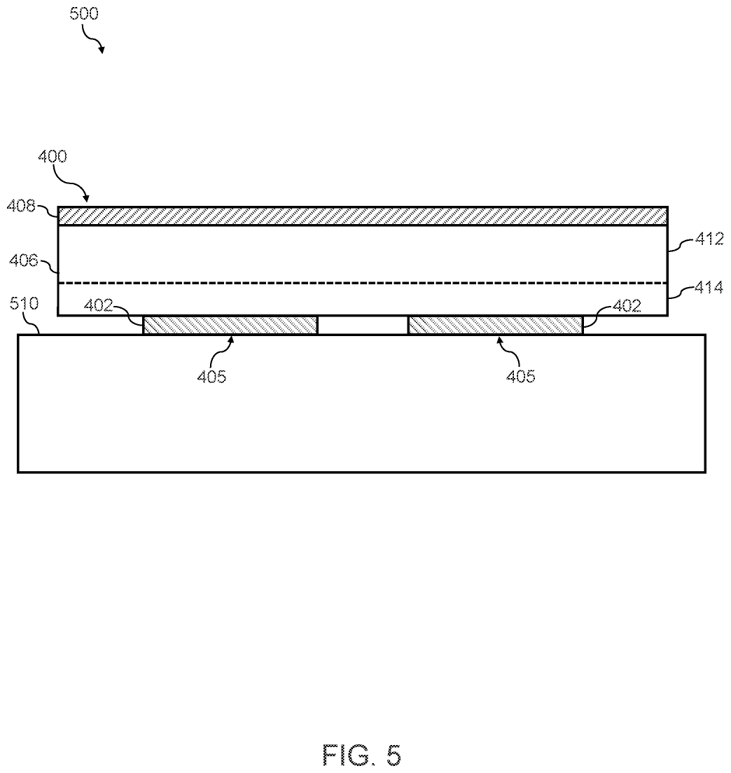

FIG. 5 depicts an example semiconductor device package 500 in a flip chip configuration according to aspects of the present disclosure. FIG. 5 is intended to represent structures for identification and description and is not intended to represent the structures to physical scale. The semiconductor device package 500 includes the semiconductor die 406 having the first metallization layer 402 on the epitaxial layer 414 and the second metallization layer 408 on the substrate 412. In some embodiments, the semiconductor die 400 is directly bonded to a submount 510 at an interface 405 between the submount 510 and first metallization layer 402 on the epitaxial layer 414 of the semiconductor die 406. For example, the first metallization layer 402 may be ultrasonically bonded to the submount 510 at the interface 405. In some embodiments, the first metallization layer 402 and the submount 510 may be a malleable metal such as aluminum, silver, or gold. For example, the first metallization layer 402 and submount 510 may be aluminum and directly bonded at the interface 405. In some embodiments, the first metallization layer 402 may include a source contact and a gate contact of one or more semiconductor devices associated with the semiconductor die 406, such as one or more transistor devices. The submount 510 may be a lead frame, clip structure, or other submount. The first metallization layer 402 may be directly bonded to the submount 510 connecting the source contact and gate contact to the submount 510.

In some embodiments (not illustrated), the semiconductor die 400 may be oriented such that the second metallization layer 408 on the substrate 412 is directly bonded to the submount 510 at an interface between the second metallization layer 408 and submount 510. For example, the second metallization layer 408 may be ultrasonically bonded to the submount 510 at the interface between the second metallization layer 408 on the substrate 412 and the submount 510. In some embodiments, the second metallization layer 408 and the submount 510 may be a malleable metal such as aluminum, silver, or gold. For example, the second metallization layer 408 and the submount 510 may be aluminum and directly bonded to each other. In some embodiments, the submount 510 may be a lead frame, clip structure or other submount. The second metallization layer 408 may include a drain contact of one or more semiconductor devices associated with the semiconductor die 406, such as one or more transistor devices. The second metallization layer 408 may be directly bonded to the submount 510 connecting the drain contact to the submount 510.

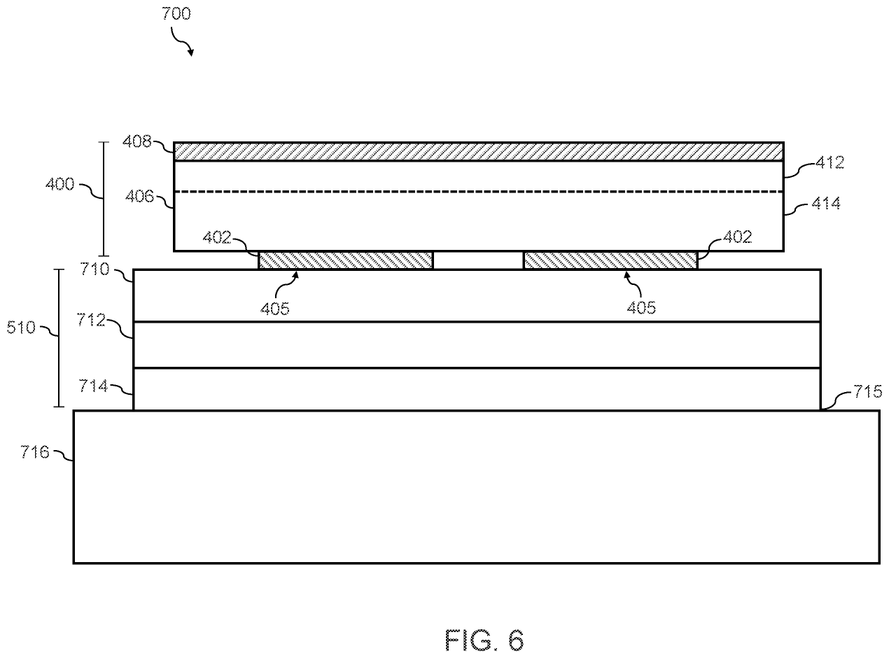

FIG. 6 depicts an example semiconductor device package 700 according to aspects of the present disclosure. FIG. 6 is intended to represent structures for identification and description and is not intended to represent the structures to physical scale. The semiconductor device package 700 may be similar to the semiconductor device package 500 shown in FIG. 5. For instance, the semiconductor die 400 may be directly bonded to the submount 510 at an interface 405 between the submount 510 and the first metallization layer 402 on the epitaxial layer 414 of the semiconductor die 406 in a flip chip configuration. Here, the submount 510 may include a first metal layer 710, a second metal layer 714, and an insulating layer 712 between the first metal layer 710 and the second metal layer 714.

In some embodiments, the first metal layer 710 may be directly bonded to the semiconductor die 400. The second metal layer 714 may be directly bonded, for instance, to a second submount 716 (e.g., lead frame, clip structure, heat sink, etc.). For instance, the first metallization layer 402 may be ultrasonically bonded to the first metal layer 710 at an interface 405 between the semiconductor die 400 and the submount 510. The second metal layer 714 may be ultrasonically bonded to the second submount 716 at an interface 715 between the submount 510 and the second submount 716. In some embodiments, the metal layers 710, 714 and second submount 716 may be made of a malleable metal such as, aluminum, silver, or gold. The insulating layer 712 may be made of an insulating material such as a ceramic material.

In some embodiments (not shown), the semiconductor die 400 may be oriented such that the second metallization layer 408 may be directly bonded to the first metal layer 710 of the submount 510. For example, the second metallization layer 408 and first metal layer 710 may be ultrasonically bonded together. It should be appreciated, using the disclosures provided herein, that the semiconductor die 400, the submount 510, and the second submount 716 may be directly bonded to one another, and arranged or oriented, in a plurality of ways without deviating from the scope of the present disclosure.

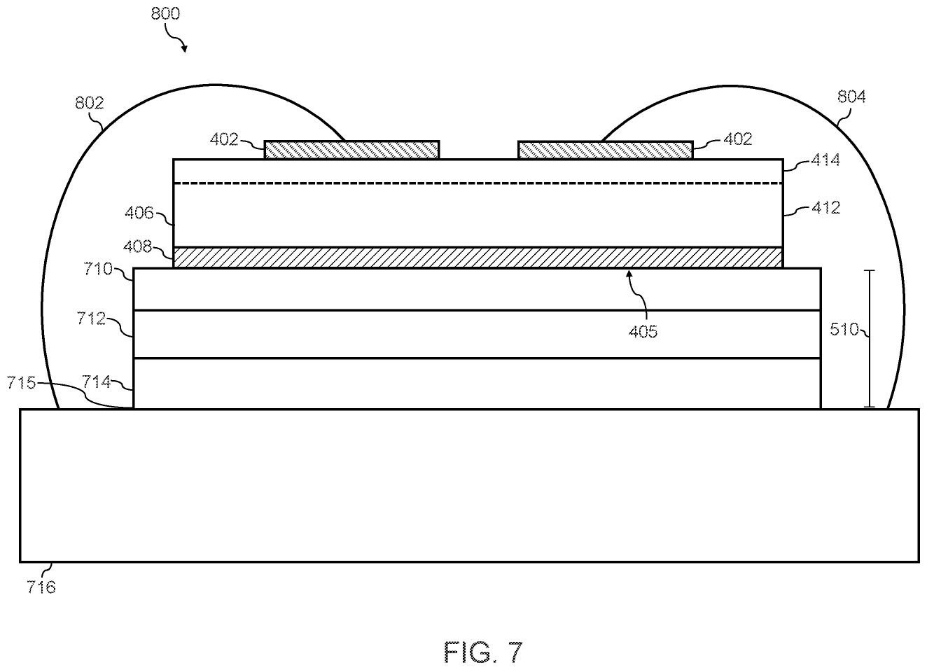

FIG. 7 depicts an example semiconductor device package 800 according to example aspects of the present disclosure. FIG. 7 is intended to represent structures for identification and description and is not intended to represent the structures to physical scale. In the example of FIG. 7, the semiconductor die 400 is mounted such that the second metallization layer 408 on the substrate 412 of the semiconductor die 400 is directly bonded to the first metal layer 710 of the submount 510 at an interface 405 between the submount 510 and the semiconductor die 400. For example, the second metallization layer 408 may be ultrasonically bonded to the first metal layer 710 at the interface 405 between the submount 410 and the semiconductor die 400. The first metallization layer 402 on the epitaxial layer 414 of the semiconductor die 402 may be connected to the second submount 716 via wire bonds 802, 804.

In some embodiments (not shown), the semiconductor die 400 is in a flip chip configuration where the first metallization layer 402 on the epitaxial layer 414 of the semiconductor die 400 is directly bonded to the first metal layer 710 of the submount 510. The second metallization layer 408 on the substrate 412 may be facing away from the submount 510 and connected to the second submount 716 via wire bonds 802, 804.

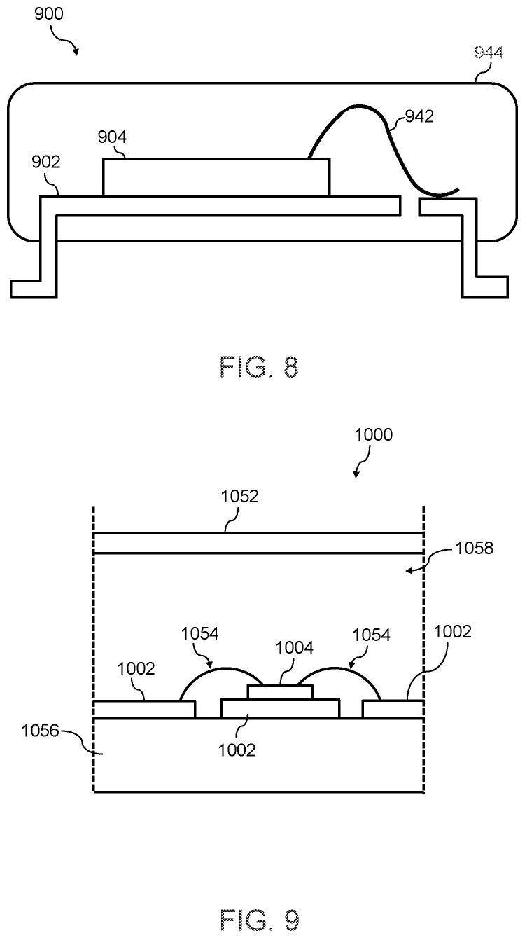

FIG. 8 depicts an example semiconductor device package 900 including a semiconductor die 904 attached to a submount 902 according to example embodiments of the present disclosure. FIG. 8 is intended to represent structures for identification and description and is not intended to represent the structures to physical scale. As shown, the semiconductor device package 940 may include a submount 902 (e.g., aluminum lead frame) directly bonded to a semiconductor die 904, as discussed above with reference to FIGS. 2-7. FIG. 8 depicts one example semiconductor device package 940 for purposes of illustration and discussion. Those of ordinary skill in the art, using the disclosures provided herein, will understand that aspects of the present disclosure may be used in a variety of devices and/or applications without deviating from the scope of the present disclosure.

The semiconductor device package 940 may be, for instance, a discrete semiconductor device package. The semiconductor device package 940 may include the conductive submount 902 (e.g., an aluminum lead frame) on which a semiconductor die 904 containing one or more power devices (e.g., transistors, diodes, etc.) is attached using a direct bonding process as described with reference to FIGS. 2-7 according to example embodiments of the present disclosure. The direct bonding process may be, for example, an ultrasonic bonding process. The direct bonding process may utilize metallization layers on the semiconductor die 904 and submount 902. In some embodiments, the semiconductor die 904 may also be connected to a portion of the conductive submount 902 using wire bonds 942. An encapsulating material 944 (e.g., epoxy mold compound (EMC)) may fill the space around the semiconductor die 904 and the submount 902.

FIG. 9 depicts a cross-sectional view of a portion of a power module 1000 according to example embodiments of the present disclosure. FIG. 9 is intended to represent structures for identification and description and is not intended to represent the structures to physical scale. The power module 1000 may include a housing 1052. The power module 1000 may include a conductive submount 1002 (e.g., an aluminum lead frame) on which a semiconductor die 1004 containing one or more power devices (e.g., transistors, diodes, etc.) is attached using a direct bonding process described with reference to FIGS. 2-7 according to example embodiments of the present disclosure. The direct bonding process may be, for example, an ultrasonic bonding process. In some embodiments, the semiconductor die 1004 may also be connected to the conductive submount 1002 using wire bonds 1054. The conductive submount 1002 may be mounted on a base layer 1056 (e.g., an insulating layer). An inert gel 1058 may fill the space between the semiconductor die 1004 and the housing 1052.

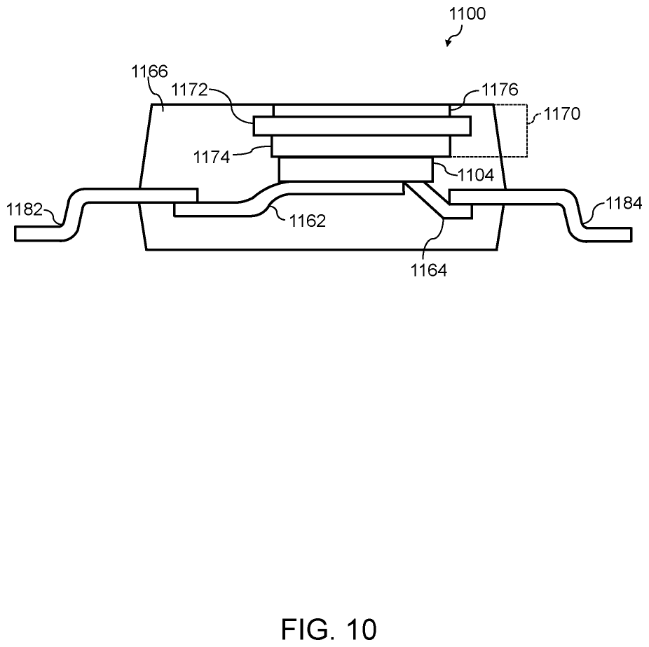

FIG. 10 depicts an example semiconductor device package 1100 according to example embodiments of the present disclosure. FIG. 10 is intended to represent structures for identification and description and is not intended to represent the structures to physical scale. The semiconductor device package 1100 may include one or more clip structures, such as clip structure 1162 and clip structure 1164. The clip structure 1162 may be conductively coupled to the lead 1182 of the semiconductor device package 1100.

The clip structure 1164 may be conductively coupled to the lead 1184 of the semiconductor device package 1100. The clip structure 1164 may be coupled to a submount 1170. The submount 1170 may include a first conductive layer 1174 (e.g., patterned aluminum layer) and a second conductive layer 1176 (e.g., patterned aluminum layer) separated by an insulating layer 1172 (e.g., ceramic layer). The clip structure 1164 may be conductively coupled, for instance, to a first conductive layer 1174 of the submount 1170. The second conductive layer 1176 of the submount 1170 may provide a topside cooling layer for the semiconductor device package 1100 in some examples.

According to example aspects of the present disclosure, the semiconductor die 1104 (e.g., containing one or more power devices) may be attached to the clip structure 1162 using a direct bonding process as discussed above with reference to FIGS. 2-7. Similarly, in some examples, the semiconductor die 1104 may be attached to the submount 1170 (e.g., to the first conductive layer 1174) using a direct bonding process such as, for example, an ultrasonic bonding process as discussed above with reference to FIGS. 2-7. An insulating layer 1166 (e.g., EMC) may be on or cover the semiconductor die 1104, clip structure 1162, clip structure 1164, DBC submount 1170 and other structures of the semiconductor device package 1100.

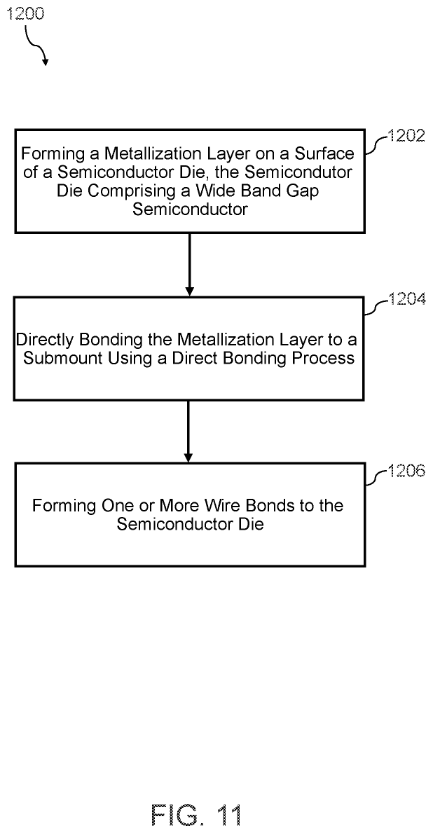

FIG. 11 depicts an example method 1200 of providing a semiconductor device package according to example aspects of the present disclosure. FIG. 11 depicts operations performed in a particular order for purposes of illustration and discussion. Those of ordinary skill in the art, using the disclosures provided herein, will understand that various operations of any of the methods described herein can be adapted, expanded, omitted, rearranged, include steps or operations not illustrated, and/or modified in various ways without deviating from the scope of the present disclosure.

At 1202, the method includes providing a metallization layer on a surface of a semiconductor die. The semiconductor die may be a wide bandgap semiconductor die that includes a wide bandgap semiconductor material. The metallization layer may be provided, for instance, on an epitaxial layer and/or on a substrate of the semiconductor die. The metallization layer may be provided, for instance, using a suitable deposition process, such as suitable metal deposition process, such as a chemical vapor deposition (CVD) process, a physical vapor deposition (PVD) process, a sputtering process, an atomic layer deposition (ALD) process, or other suitable deposition process.

In some embodiments, the metallization layer may be a malleable material, such as aluminum, silver, or gold. In some embodiments, the semiconductor device package may include an encapsulating material on the semiconductor die. For example, the semiconductor device package may include an epoxy mold compound on the semiconductor die.

In some embodiments, the metallization layer may be associated with a contact for one or more semiconductor devices on the semiconductor die. For instance, the metallization layer may include a source, gate, and drain contact for a semiconductor device, such as a transistor device associated with the semiconductor die. In another embodiment, the metallization layer may be associated with a plurality of different contacts for one or more semiconductor devices on the semiconductor die. For example, the metallization layer may include several source contacts, drain contacts, and gate contacts associated with several semiconductor devices, such as transistor devices associated with the semiconductor die. For example, the semiconductor die may include silicon carbide-based MOSFETs, silicon carbide-based Schottky diodes, or Group III nitride-based HEMTs.

At 1204, the method includes directly bonding the metallization layer to a submount using a direct bonding process. For example, the metallization layer of the semiconductor die may be directly bonded to a submount via an ultrasonic bonding process at an interface between the submount and the metallization layer. The submount may include a malleable material (e.g., the same material as the metallization layer), such as aluminum, silver, or gold. In this way, the semiconductor device package includes a malleable metal at an interface between the metallization layer and the submount. For instance, the metallization layer and the submount may each include aluminum at the interface between the metallization layer and the submount. The metallization layer and the submount may each include gold at the interface between the metallization layer and the submount. The metallization layer and the submount may each include silver at the interface between the metallization layer and the submount. There is no die-attach material at the interface between the semiconductor die and the submount.

In some embodiments, the submount may be a lead frame, clip structure or other submount. In some embodiments, the semiconductor die may be in a flip chip configuration with the submount and directly bonded to the submount. In some embodiments, the submount may include a first metal layer, a second metal layer, and an insulating layer between the first metal layer and the second metal layer. For example, the first and second metal layers may be a malleable metal, such as aluminum, silver, or gold, and the insulating material may be a ceramic material.

In some embodiments, the submount and/or the metallization layer may have a surface roughness measured as arithmetic average roughness Ra in a range of about 0.1 μm to about 100 μm, such as about 0.5 μm to about 20 μm, such as about 0.5 μm to about 10 μm to facilitate the direct bonding process. In some embodiments, the submount may include aluminum, and the surface of the submount opposite of the semiconductor die may be an anodized surface.

At 1206, the method may include providing one or more wire bonds to the semiconductor die. For example, the semiconductor die may use wire bonds to connect a metallization layer on a side of the semiconductor die facing away from the direct bond between the semiconductor die and the submount. The wire bonds may be bonded to the semiconductor die (e.g., to a metallization layer) using, for instance, an ultrasonic bonding process.

Example aspects of the present disclosure are set forth below. Any of the below features or examples may be used in combination with any of the embodiments or features provided in the present disclosure.

One example aspect of the present disclosure is directed to a semiconductor device package. The semiconductor device package includes a semiconductor die. The semiconductor die includes a wide bandgap semiconductor material. The semiconductor die includes a metallization layer on a surface of the semiconductor die. The semiconductor device package includes a submount. The metallization of the semiconductor die is directly bonded to the submount.

In some examples, the metallization layer and the submount each comprise a malleable metal at an interface between the metallization layer and the submount.

In some examples, the metallization layer and the submount comprise aluminum at the interface between the metallization layer and the submount.

In some examples, the metallization layer and the submount comprise silver at the interface between the metallization layer and the submount.

In some examples, the metallization layer and the submount comprise gold at the interface between the metallization layer and the submount.

In some examples, the metallization layer of the semiconductor die is directly bonded to the submount via an ultrasonic bond.

In some examples, the surface of the submount comprises a surface roughness measured as arithmetic average roughness Ra in a range of about 0.1 μm to about 100 μm.

In some examples, the semiconductor device package does not include any die-attach material at an interface between the metallization layer and the submount.

In some examples, the submount comprises aluminum, and wherein a surface of the submount opposite the semiconductor die is an anodized surface.

In some examples, the submount is a lead frame or a clip structure.

In some examples, the submount comprises a first metal layer, a second metal layer, and an insulating material between the first metal layer and the second metal layer.

In some examples, the submount is mounted to a lead frame.

In some examples, the metallization layer is associated with a contact for one or more semiconductor devices on the semiconductor die.

In some examples, the metallization layer is associated with a plurality of different contacts for one or more semiconductor devices on the semiconductor die.

In some examples, the metallization layer is on a substrate of the semiconductor die.

In some examples, the metallization layer is on an epitaxial layer of the semiconductor die.

In some examples, the semiconductor die is mounted in a flip chip configuration with the submount.

In some examples, the semiconductor device package further comprises one or more wire bonds to the semiconductor die.

In some examples, the semiconductor device package further comprises an encapsulating material on the semiconductor die.

In some examples, the encapsulating material comprises an epoxy mold compound.

In some examples, the semiconductor die comprises silicon carbide.

In some examples, the semiconductor die comprises a Group III nitride.

In some examples, the semiconductor die comprises a silicon carbide-based MOSFET, a silicon carbide-based Schottky diode, or a Group III nitride-based high electron mobility transistor.

Another example aspect of the present disclosure is directed to a semiconductor device package. The semiconductor device package includes a semiconductor die. The semiconductor die includes a wide bandgap semiconductor material. The semiconductor die includes a metallization layer on a surface of the semiconductor die. The semiconductor device package includes an aluminum lead frame.

In some examples, an interface between the metallization layer and the aluminum lead frame comprises an ultrasonic bond between the metallization layer and the aluminum lead frame.

In some examples, the metallization layer comprises aluminum.

In some examples, the semiconductor device package does not include any die-attach material at an interface between the semiconductor die and the aluminum lead frame.

In some examples, a surface of the aluminum lead frame opposite to the semiconductor die is an anodized surface.

In some examples, the metallization layer is associated with a contact for one or more semiconductor devices on the semiconductor die.

In some examples, the metallization layer is associated with a plurality of different contacts for one or more semiconductor devices on the semiconductor die.

In some examples, the metallization layer is on a substrate of the semiconductor die.

In some examples, the metallization layer is on an epitaxial layer.

In some examples, the semiconductor die is mounted in a flip chip configuration with the aluminum lead frame.

In some examples, the semiconductor device package further comprises one or more wire bonds to the semiconductor die.

In some examples, the semiconductor device package further comprises an encapsulating material on the semiconductor die.

In some examples, the encapsulating material comprises an epoxy mold compound.

In some examples, the semiconductor die comprises silicon carbide.

In some examples, the semiconductor die comprises a Group III nitride.

In some examples, the semiconductor die comprises a silicon carbide-based MOSFET, a silicon carbide-based Schottky diode, or a Group III nitride-based high electron mobility transistor.

Another example aspect of the present disclosure is directed to a method of providing a semiconductor device package. The method includes providing a metallization layer on a surface of a semiconductor die. The semiconductor die includes a wide bandgap semiconductor. The method includes directly bonding the metallization layer to a submount using a direct bonding process.

In some examples, the direct bonding process comprises an ultrasonic bonding process.

In some examples, the surface of the submount comprises a surface roughness measured as arithmetic average roughness Ra in a range of about 0.1 μm to about 100 μm.

In some examples, the metallization layer and the submount comprise a malleable metal at an interface between the metallization layer and the submount.

In some examples, the metallization layer and the submount comprise aluminum at the interface between the metallization layer and the submount.

In some examples, the submount is a lead frame.

In some examples, directly bonding the metallization layer to the submount does not include a die-attach material at an interface between the semiconductor die and the submount.

In some examples, the submount comprises aluminum, and wherein a surface of the submount opposite the semiconductor die is an anodized surface.

In some examples, the submount comprises a first metal layer, a second metal layer, and an insulating layer between the first metal layer and the second metal layer.

In some examples, the metallization layer is associated with a contact for one or more semiconductor devices on the semiconductor die.

In some examples, the metallization layer is associated with a plurality of different contacts for one or more semiconductor devices on the semiconductor die.

In some examples, the metallization layer is on a substrate of the semiconductor die. In some examples, the metallization layer is on an epitaxial layer.

In some examples, the semiconductor die is mounted in a flip chip configuration with the submount.

In some examples, the method comprises providing one or more wire bonds to the semiconductor die.

In some examples, an encapsulating material is on the semiconductor die.

In some examples, the encapsulating material comprises an epoxy mold compound.

In some examples, the semiconductor die comprises silicon carbide.

In some examples, the semiconductor die comprises a Group III nitride.

In some examples, the semiconductor die comprises a silicon carbide-based MOSFET, a silicon carbide-based Schottky diode, or a Group III nitride-based high electron mobility transistor.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device package, comprising:
a semiconductor die, comprising:
a wide bandgap semiconductor material; and
a metallization layer on a surface of the semiconductor die;
a submount; and
wherein the metallization layer of the semiconductor die is directly bonded to the submount.

2. The semiconductor device package of claim 1, wherein the metallization layer and the submount each comprise a malleable metal at an interface between the metallization layer and the submount.

3. The semiconductor device package of claim 2, wherein the malleable metal comprises gold, aluminum, or silver.

4.-5. (canceled)

6. The semiconductor device package of claim 1, wherein the metallization layer of the semiconductor die is directly bonded to the submount via an ultrasonic bond.

7. The semiconductor device package of claim 6, wherein the surface of the submount comprises a surface roughness measured as arithmetic average roughness Ra in a range of about 0.1 μm to about 100 μm.

8. The semiconductor device package of claim 1, wherein the semiconductor device package does not include any die-attach material at an interface between the metallization layer and the submount.

9. The semiconductor device package of claim 1, wherein the submount comprises aluminum, and wherein a surface of the submount opposite the semiconductor die is an anodized surface.

10. The semiconductor device package of claim 1, wherein the submount is a lead frame or a clip structure.

11. The semiconductor device package of claim 1, wherein the submount comprises a first metal layer, a second metal layer, and an insulating material between the first metal layer and the second metal layer.

12. The semiconductor device package of claim 11, wherein the submount is mounted to a lead frame.

13. The semiconductor device package of claim 12, wherein the metallization layer is associated with a contact for one or more semiconductor devices on the semiconductor die.

14. (canceled)

15. The semiconductor device package of claim 1, wherein the metallization layer is on a substrate of the semiconductor die.

16. The semiconductor device package of claim 1, wherein the metallization layer is on an epitaxial layer of the semiconductor die.

17. The semiconductor device package of claim 1, wherein the semiconductor die is mounted in a flip chip configuration with the submount.

18. The semiconductor device package of claim 1, further comprising one or more wire bonds to the semiconductor die.

19. The semiconductor device package of claim 1, further comprising an encapsulating material on the semiconductor die.

20. (canceled)

21. The semiconductor device package of claim 1, wherein the semiconductor die comprises silicon carbide or a Group III-nitride.

22. (canceled)

23. The semiconductor device package of claim 1, wherein the semiconductor die comprises a silicon carbide-based MOSFET, a silicon carbide-based Schottky diode, or a Group III nitride-based high electron mobility transistor.

24. A semiconductor device package, comprising:
a semiconductor die, comprising:
a wide bandgap semiconductor material; and
a metallization layer on a surface of the semiconductor die; and
an aluminum lead frame.

25.-39. (canceled)

40. A method of providing a semiconductor device package, the method comprising:
providing a metallization layer on a surface of a semiconductor die, the semiconductor die comprising a wide bandgap semiconductor; and
directly bonding the metallization layer to a submount using a direct bonding process.

41.-59. (canceled)
